(19) United States
(12) Patent Application Publication
(10) Pub. No.: US 2013/0152479 A1
(43) Pub. Date: Jun. 20, 2013

(54) HARD DISK DRIVE FILLER

(71) Applicants: Wei-Chih Kuo, Taipei City (TW); Bo-Chun Lin, Taipei City (TW)

(72) Inventors: Wei-Chih Kuo, Taipei City (TW); Bo-Chun Lin, Taipei City (TW)

(21) Appl. No.: 13/607,313

(22) Filed: Sep. 7, 2012

(30) Foreign Application Priority Data
Dec. 16, 2011 (TW) 100146864

(51) Int. Cl. H05K 5/03

(52) U.S. Cl. 49/373

(57) ABSTRACT

A hard disk drive filler (HDD filler) that is detachably installed in a case is disclosed. The HDD filler has a frame body, a pivot axis, and a rotating device; wherein the frame body defines a bottom surface and a top surface which corresponds to the bottom surface. The pivot axis is disposed in the frame body. One end of the rotating device is pivoted to the pivot axis, such that the rotating device can rotate due to gravity to stay within or be partly exposed to the frame body. If the frame body is installed into the case while the bottom surface is upward, the rotating device rotates along the pivot axis and is guided by gravity such that part of the rotating device is exposed to the frame body to stop the installation.

### BACKGROUND OF THE INVENTION

1. Field of the Invention

The present invention relates to a hard disk drive filler; more particularly, the present invention relates to a hard disk drive filler with a foolproof device.

2. Description of the Related Art

The two most common kinds of hard disk drive fillers (HDD Filler) are shown in FIG. 1 and FIG. 1a. In the prior art, the top surface 120 of the hard disk drive filler of the prior art 100 illustrated in FIG. 1 is the only correct method to install the hard disk drive filler of the prior art 100 in a server or a storage case because devices for removing electromagnetic interference are mounted on the bottom surface 130 of the hard disk drive filler of the prior art 100. However, there is no foolproof device installed in the hard disk drive filler of the prior art 100. Therefore, the technical personnel cannot immediately know whether or not the hard disk drive filler of the prior art 100 is installed in the server or storage case correctly. The installation error can be identified only when the hard disk drive filler of the prior art 100 does not work, which is not convenient for the technical staff or user.

In FIG. 1a, there is a foolproof device 110a in the hard disk drive filler of the prior art 100a, but this kind of foolproof device 110a does not work effectively. If the direction of installation is wrong, the hard disk drive filler of the prior art 100a can still be installed in the server or storage case if technical personnel apply more force. A hard disk drive filler of the prior art 100a that is not installed correctly can still work properly, but it cannot match with the server or the storage case smoothly. In addition, the appearance is not as good as the appearance of correct installation.

Therefore, there is a need to provide a new hard disk drive filler to solve the problem of the prior art.

### SUMMARY OF THE INVENTION

It is an object of the present invention to provide a hard disk drive filler with a foolproof device.

To achieve the abovementioned object, the hard disk drive filler of the present invention is detachably installed in a case. The hard disk drive filler comprises a frame body, a pivot axis, and a rotating device. The frame body defines a bottom surface and a top surface corresponding to the bottom surface. The pivot axis is located in the frame body. One end of the rotating device is pivoted to the pivot axis, such that the rotating device can rotate due to gravity to stay within the frame body or at least a part of the gravitational sliding device is exposed to the frame body. Applying the abovementioned structure, if the hard disk drive filler is installed into the case when the bottom surface is upward, the rotating device is guided to rotate along the pivot axis due to gravity, such that a part of the rotating device is exposed to the frame body for preventing the frame body form entering the case.

The hard disk drive filler of the present invention can prevent the hard disk drive filler from being installed into the case in the wrong direction.

### BRIEF DESCRIPTION OF THE DRAWINGS

FIG. 1 illustrates a schematic drawing of the hard disk drive filler of the prior art according to one embodiment.

FIG. 1a illustrates a schematic drawing of the hard disk drive filler of the prior art according to another embodiment.

FIG. 2 illustrates a schematic drawing of the hard disk drive filler of the present invention according to one embodiment when the bottom surface is upward.

FIG. 2a illustrates a schematic drawing of the assembly of the hard disk drive filler of the present invention according to one embodiment when the bottom surface is upward.

FIG. 3 illustrates a schematic drawing of the hard disk drive filler of the present invention according to one embodiment when the top surface is upward.

FIG. 3a illustrates a schematic drawing of the assembly of the hard disk drive filler of the present invention according to one embodiment when the top surface is upward.

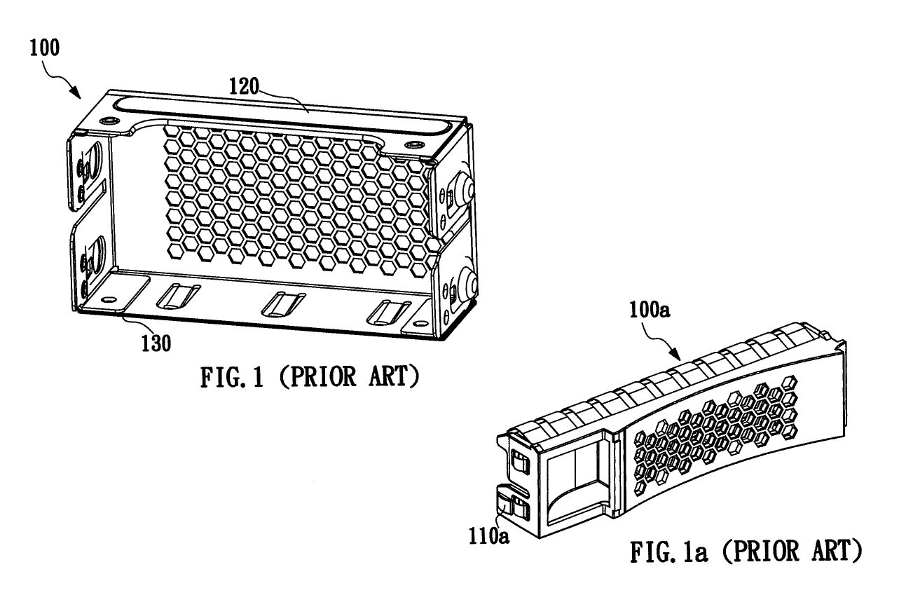

### DETAILED DESCRIPTION OF THE PREFERRED EMBODIMENT

These and other objects and advantages of the present invention will become apparent from the following description of the accompanying drawings, which disclose several embodiments of the present invention. It is to be understood that the drawings are to be used for purposes of illustration only, and not as a definition of the invention.

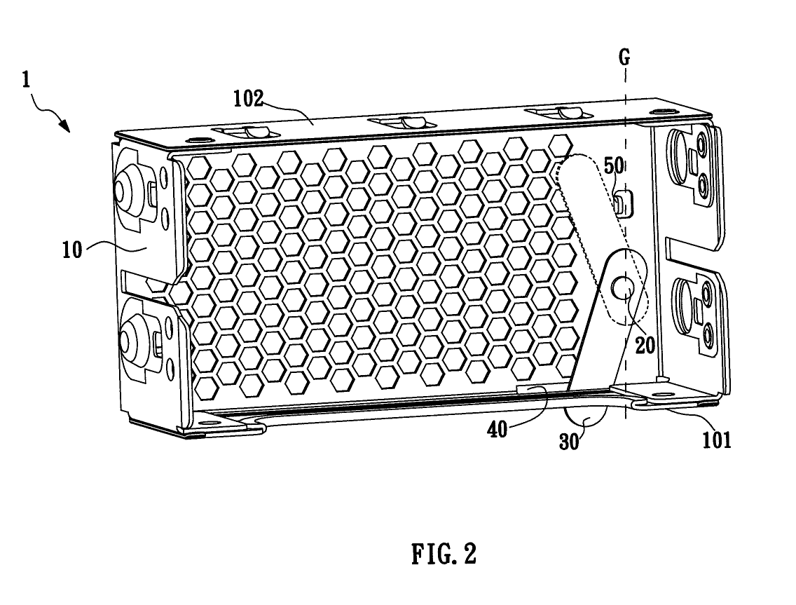

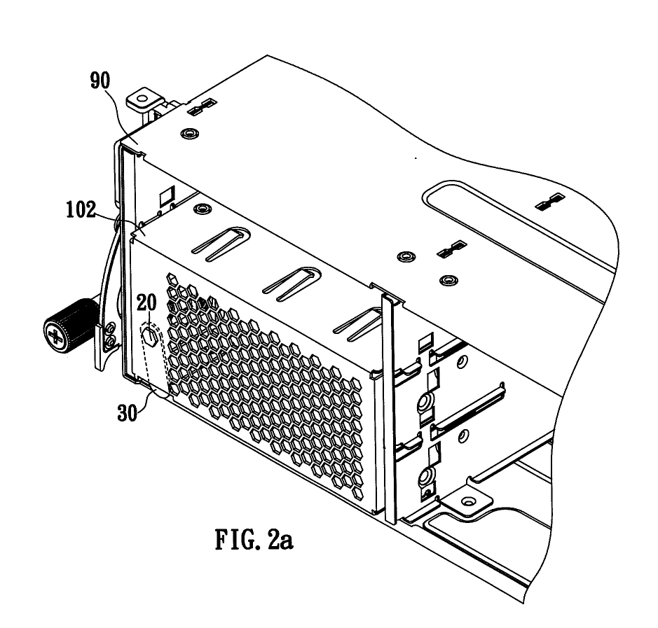

Please refer to FIG. 2 and FIG. 2a for the hard disk drive filler according to one embodiment of the present invention. FIG. 2 illustrates a schematic drawing of the hard disk drive filler of the present invention according to one embodiment when the bottom surface is upward; FIG. 2a illustrates a schematic drawing of the assembly of the hard disk drive filler of the present invention according to one embodiment when the bottom surface is upward.

As shown in FIG. 2, the hard disk drive filler 1 of the present invention comprises a frame body 10, a pivot axis 20, a rotating device 30, a hole 40, and a stopper 50. The frame body 10 defines a top surface 101 and a bottom surface 102 which corresponds to the bottom surface 101. The pivot axis 20 is located in the frame body 10 or other suitable places; one end of the rotating device 30 is pivoted to the pivot axis 20. The hole 40 is on the top surface 101 and the rotating path of the rotating device 30. The stopper 50 is located on a position between the pivot axis 20 and the bottom surface 102; the position is equivalent to the position of the gravity line G which passes through the pivot axis 20, or equivalent to a position shifted towards inside and deviated from the gravity line G. It is noted that the position must allow the rotating device 30 not to go beyond the gravity line G when the rotating device 30 rotates inward in the hole 40, which means that the rotating device 30 is restricted to rotation in the inside range, such that when the bottom surface 102 of the hard disk drive filler 1 is upward, the rotating device 30 will rotate inward and drop due to gravity, to pass through the hole 40 and be partly exposed to the frame body 10. A better embodiment of the present invention is that the hole 40 faces toward the inside and shifts away from the gravity line G, but the present invention is not limited to that design.

It is to be understood that, in the present invention, the top surface 101 and the bottom surface 102 of the frame body 10 can represent a non-existent top surface and bottom surface; for example, the top surface 101 can be an open space, which means that the top surface 101 and the bottom surface 102 can represent an upper side and a lower side which is opposite to the upper side of the space, and the open space of the top surface 101 can also represent as a large hole 40. As shown in FIG. 2a, the hard disk drive filler 1 of the present invention is detachably installed in the case 90. In the present embodiment, the direction of installation is wrong when the bottom surface 102 of the hard disk drive filler 1 is upward. If the hard disk drive filler 1 is installed in the case 90 with the bottom surface 102 upward, the rotating device 30 rotates along the pivot axis 20 via gravity; at this moment, the rotating device 30 rotates out of the frame body 10, and the end part of the rotating device 30 is exposed to the frame body 10 for interfering with the frame body of the case 90 to block the frame body 10 from the case 90, and to prevent the hard disk drive filler 1 from being installed in the case 90 in the wrong direction. It is to be understood that, to obtain a better gravitational rotating effect, the rotating device 30 must have a certain weight, and the rotating device 30 of the present embodiment is made of a zinc coating on hot-dipped steel (SGCC), but the present invention is not limited to that design. Any material with sufficient weight can be applied to the present invention, and the case 90 can be the case of a server or a storage case.

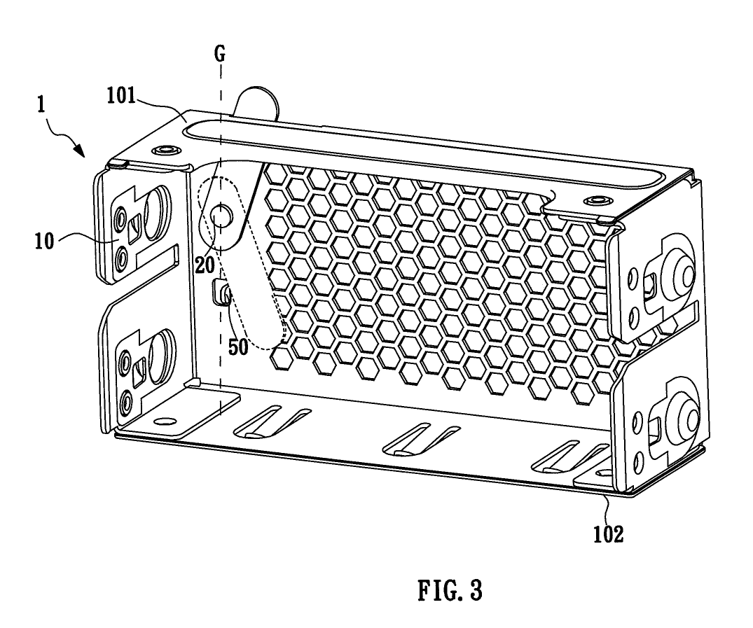

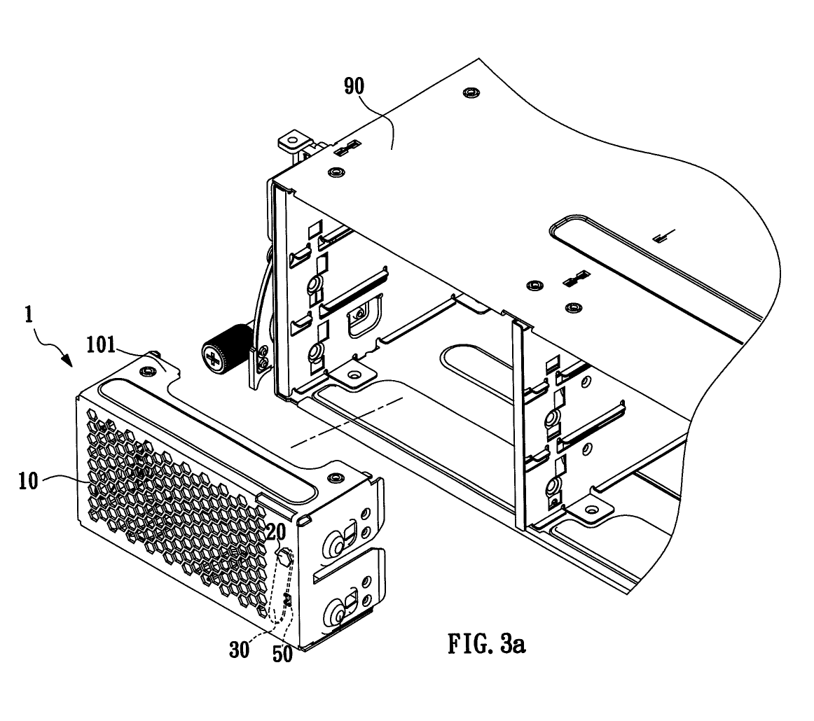

Please refer to FIG. 3 and FIG. 3a, wherein FIG. 3 illustrates a schematic drawing of the hard disk drive filler of the present invention according to one embodiment when the top surface is upward; FIG. 3a illustrates a schematic drawing of the assembly of the hard disk drive filler of the present invention according to one embodiment when the top surface is upward.

As shown in FIG. 3 and FIG. 3a, in the present embodiment, the correct direction of installation of the hard disk drive filler 1 is with the top surface 101 is upward. Therefore, when the hard disk drive filler 1 is installed in the case 90 when the top surface 101 is upward, the rotating device 30 is located on the hole 40, and it is shifted from the gravity line G in a shifting status, such that the rotating device 30 will automatically rotate inward to the frame body 10 along the abovementioned rotating direction and range due to gravity, to stay within the frame body 10 until the rotating device 30 touches the stopper 50 for allowing the hard disk drive filler 1 to be installed to the case 90. The rotating device 30 is stopped from rotating toward the outside of the gravity line G by the stopper 50 to prevent the rotating device 30 from rotating toward the outside and being blocked by the frame body 10, being stuck on the side wall, being unable to rotate inward, and being exposed to the hole 40 when the whole system reverses. It is to be understood that according to one embodiment of the present invention, the hole 40 is opposite to the stopper 50 across the pivot axis 20; the hole 40 also forms a restricting rotating area of the rotating device 30 with the stopper 50. Due to the design of the position of the hole 40 and the stopper 50, the largest rotating angle of the restricting rotating area of the rotating device 30 is substantially smaller than 160°. However, the present invention is not limited to that design; the largest rotating angle of the restricting rotating area of the rotating device 30 can be also substantially smaller than 180°.

Applying the abovementioned structure, if the hard disk drive filler 1 of the present invention is installed in the case 90 in the wrong direction, the end part of the rotating device 30 rotates out of the frame body 10 and is exposed to the frame body 10 due to gravity for allowing the frame body to be blocked from the case 90, such that the technical personnel immediately know that the installation is incorrect and a correction can be made.

It is noted that the above-mentioned embodiments are only for illustration. It is intended that the present invention cover modifications and variations of this invention provided they fall within the scope of the following claims and their equivalents. Therefore, it will be apparent to those skilled in the art that various modifications and variations can be made to the structure of the present invention without departing from the scope or spirit of the invention.

What is claimed is:

1. A hard disk drive filler detachably installed in a case, the hard disk drive filler comprising:
a frame body defining a bottom surface and a top surface corresponding to the bottom surface;
a pivot axis located in the frame body; and
a rotating device; one end of the rotating device is pivoted to the pivot axis such that the rotating device can rotate due to gravity to stay within or be partly exposed to the frame body;
whereby, if the hard disk drive filler is installed into the case when the bottom surface is upward, the rotating device is guided by gravity to rotate along the pivot axis, until a part of the rotating device is exposed to the frame body to block the frame body and keep it outside the case.

2. The hard disk drive filler as claimed in claim 1, wherein the hard disk drive filler further comprises a hole; the hole is located on the top surface and on a rotating path of the rotating device for allowing an end part of the rotating device to be exposed to the frame body.

3. The hard disk drive filler as claimed in claim 2, wherein the top surface can be represented as an open space, and the hole is the open space.

4. The hard disk drive filler as claimed in claim 1, wherein if the hard disk drive filler is installed in the case when the top surface is upward, the rotating device is guided to rotate to stay within the frame body without being exposed due to gravity.

5. The hard disk drive filler as claimed in claim 1, wherein a gravity line is defined by a position of the pivot axis and two rotating areas are separated by the gravity line.

6. The hard disk drive filler as claimed in claim 5, wherein the hard disk drive filler further comprises a stopper located in a position which is equivalent to a position of the gravity line or a position shifted towards the inside; when the rotating device is guided to rotate to an appropriate position in the frame body by the gravity, the rotating device is blocked by the stopper.

7. The hard disk drive filler as claimed in claim 6, wherein a position of the hole is equivalent to the position of the gravity line or the position shifted towards the inside, and opposite to the stopper while the pivot axis is disposed between the hole and the stopper, and the hole and the stopper form a restricting rotating area of the rotating device.

8. The hard disk drive filler as claimed in claim 7, wherein the largest rotating angle of the restricting rotating area of the rotating device is substantially smaller than 180°.

9. The hard disk drive filler as claimed in claim 7, wherein the largest rotating angle of the restricting rotating area of the rotating device is substantially smaller than 160°.
